(19) United States
(12) Patent Application Publication
(10) Pub. No.: US 2026/0055256 A1
(43) Pub. Date: Feb. 26, 2026

(54) RESIN COMPOSITION, ELECTRONIC COMPONENT DEVICE AND METHOD OF PRODUCING ELECTRONIC COMPONENT DEVICE

(71) Applicant: RESONAC CORPORATION, Tokyo (JP)

(72) Inventors: Yuta SUKEGAWA, Tokyo (JP); Mika TANAKA, Tokyo (JP); Yuma TAKEUCHI, Tokyo (JP); Shintaro OKADA, Tokyo (JP)

(21) Appl. No.: 18/862,137

(22) PCT Filed: Jun. 10, 2022
(86) PCT No.: PCT/JP2022/023506

§ 371 Date: Nov. 5, 2025

(51) Int. Cl. C08K 3/06; C08K 3/04; C08K 5/42; C08K 5/544; H01L 21/56; H01L 23/29

(52) U.S. Cl. CPC C08K 3/06; C08K 3/04; C08K 5/42; C08K 5/544; H01L 21/56; H01L 23/295; C08K 2201/005; C08K 2201/006

(57) ABSTRACT

A resin composition includes a compound having an oxazoline group, a phenol type curing agent, and an inorganic filler.

### TECHNICAL FIELD

The present disclosure relates to a resin composition, an electronic component device, and a method of producing an electronic component device.

### BACKGROUND ART

An amount of transmission loss that occurs when radio waves transmitted for communication are converted into heat in a dielectric is expressed as a product of a frequency, a square root of a relative dielectric constant, and a dielectric loss tangent. That is, since a transmission signal is easily converted into heat in proportion to its frequency, in order to suppress transmission loss, the higher the frequency of the transmission signal, the lower the dielectric properties required for materials of a communication component.

A sealing resin composition containing an epoxy resin and a phenol type curing agent are widely used in electronic component applications, and in recent years, a cured product of a sealing resin composition is required to have a low relative dielectric constant and a dielectric loss tangent.

For example, Patent Document 1 studies a sealing resin composition with a low relative dielectric constant in the cured product, and describes a composition containing an epoxy resin and a phenolic resin.

### RELATED ART DOCUMENTS

### Patent Documents

Patent Document 1: Japanese Patent Application Laid-Open (JP-A) No. 2001-40182

### SUMMARY OF INVENTION

The present inventors have found that there is room for further improvement in a dielectric loss tangent of a cured product of a sealing resin composition disclosed in Patent Document 1.

An object of one embodiment in the present disclosure is to provide a resin composition having a low dielectric loss tangent of a cured product, an electronic component device sealed with the resin composition, and a method of producing an electronic component device, which includes sealing with the resin composition.

### Solution to Problem

<1> A resin composition including a compound having an oxazoline group, a phenol type curing agent, and an inorganic filler.
<2> The resin composition according to claim 1, in which the compound having an oxazoline group includes an aromatic oxazoline compound.
<3> The resin composition according to <1> or <2>, in which a molecular weight of the compound having an oxazoline group is from 100 to 1000.
<4> The resin composition according to any one of <1> to <3>, in which an equivalent ratio of a phenolic hydroxyl group of the phenol type curing agent to the oxazoline group of the compound having an oxazoline group is from 0.75 to 1.25.
<5> The resin composition according to any one of <1> to <4>, further including at least one of a sulfonic acid type curing accelerator or a phosphoric acid type curing accelerator.
<6> The resin composition according to any one of <1> to <5>, the resin composition being solid at 25° C.
<7> The resin composition according to any one of <1> to <6>, the resin composition having a curing initiation temperature of 175° C. or less.
<8> The resin composition according to any one of <1> to <7>, which is a resin composition for use as a sealing material.
<9> An electronic component device including:
   a support member,
   an element disposed on the support member, and
   a cured product of the resin composition according to any one of <1> to <8> that seals the element.
<10> A method of producing an electronic component device, the method including:
   disposing an element on or above a support member; and
   sealing the element with the resin composition according to any one of <1> to <8>.

### Advantageous Effects of Invention

According to the present disclosure, it is possible to provide a resin composition having a low dielectric loss tangent of a cured product, an electronic component device sealed with the resin composition, and a method of producing an electronic component device, which includes sealing with the resin composition.

### DESCRIPTION OF EMBODIMENTS

Hereinafter, embodiments in the present disclosure will be described in detail. It is to be noted, however, that the present disclosure is not limited to the following embodiments. In the embodiments described below, components thereof (including element steps and the like) are not essential, unless otherwise specified. The same applies to numerical values and ranges thereof, and the present disclosure is not limited thereto.

In the present disclosure, the term “process” includes not only a process independent of other processes, but also a process that cannot be clearly distinguished from other processes, as long as the purpose of the process is achieved.

In the present disclosure, a numerical ranges indicated using “to” include the numerical values before and after “to” as the minimum and maximum values, respectively.

In the present disclosure, in the numerical ranges described step by step in the present disclosure, the upper limit or lower limit of one numerical range may be replaced with the upper or lower limit of another numerical range described step by step. Moreover, in the numerical ranges described in the present disclosure, the upper or lower limits of the numerical ranges may be replaced with the values shown in the examples.

In the present disclosure, each component may contain multiple types of applicable substances. In a case in which a composition contains multiple substances corresponding to each component, a content or amount of each component means a total content or amount of the multiple substances present in the composition, unless otherwise specified.

In the present disclosure, particles corresponding to each component may include multiple types. In a case in which multiple types of particles corresponding to each component are present in the composition, a particle size of each component means a value for a mixture of the multiple types of particles present in the composition, unless otherwise specified.

### <Resin Composition>

A resin composition in the present disclosure (hereinafter also referred to as the specific resin composition) contains a compound having an oxazoline group (hereinafter also referred to as the oxazoline compound), a phenol type curing agent, and an inorganic filler.

The specific resin composition has a low dielectric loss tangent of cured product thereof and can be suitably used as a resin composition for a sealing material. The reason for the above effect is not clear, but is presumed to be as follows.

In a case in which a cured product is produced using a resin composition for a sealing material containing an epoxy resin and a phenol type curing agent, a reaction product of the epoxy resin and the phenol type curing agent has a secondary hydroxyl group with high polarity, and therefore tends to increase the dielectric loss tangent. The specific resin composition contains an oxazoline compound instead of an epoxy resin, and since a reaction product of the oxazoline compound and the phenol type curing agent does not have a secondary hydroxyl group, it is presumed that a dielectric loss tangent of the cured product is reduced.

From the viewpoint of improving a heat resistance of a cured product thereof, a glass transition temperature of the specific resin composition is preferably from 85° C. to 150° C., more preferably from 90° C. to 145° C., and even more preferably from 100° C. to 135° C. In the present disclosure, the glass transition temperature is determined from a DSC curve obtained by differential scanning calorimetry (DSC), and more specifically, is determined from the “extrapolated glass transition onset temperature” described in a method for determining the glass transition temperature in “Testing methods for transition temperatures of plastics” in JIS K 7121 (1987).

The specific resin composition is preferably solid at 25° C. In a case in which the specific resin composition is solid at 25° C., its shape is not particularly limited, and examples thereof include powder, granules and tablet. In a case in which the specific resin composition is in tablet form, it is preferable from the viewpoint of handleability that a dimension and a mass are set to a dimension and a mass that are suitable for a molding condition for forming a package.

A curing start temperature of the specific resin composition is preferably 200° C. or less, more preferably 190° C. or less, and even more preferably 175° C. or less. By setting the curing start temperature of the specific resin composition to 200° C. or less, a requirement for a curing equipment may be reduced, and a cured product may be easily produced. The lower limit of the curing start temperature is not particularly limited, and may be 100° C. or more.

In the present disclosure, the curing start temperature is measured by differential scanning calorimetry (DSC). To measure the curing start temperature, Discovery DSC 250 manufactured by TA instruments or an instrument with equivalent performance may be used. The curing start temperature is measured in the range from 40° C. to 300° C. at a heating rate of 10° C./min, and a peak onset temperature (peak rise temperature) is taken as the curing start temperature.

From the viewpoint of adhesion to an electronic component device such as lead frame and the like, a linear expansion coefficient of a cured product of the specific resin composition at from 80° C. to 120° C. is preferably from 0.90 ppm/° C. to 2.00 ppm/° C., more preferably from 0.95 ppm/° C. to 1.70 ppm/° C., and even more preferably from 1.00 ppm/° C. to 1.50 ppm/° C.

In the present disclosure, the linear expansion coefficient of a cured product is measured as follows.

The specific resin composition is molded using a transfer molding machine under conditions of a molding temperature of 175° C., a molding pressure of 6.9 MPa, and a curing time of 120 seconds to obtain a plate-shaped molded product (length 127 mm, width 12.7 mm, and thickness 6.4 mm).

Next, using thermomechanical analysis method in accordance with JIS K 7197:2012, slopes of a tangent when a distortion of the molded product is plotted against a temperature are determined in the ranges from 80° C. to 120° C. and from 200° C. to 240° C. respectively, and these are taken as the linear expansion coefficient.

A test load during measurement is 5 g and a heating rate is 5° C./min.

The linear expansion coefficient may be measured using a TMA high-precision two-sample thermal analyzer (instrument name SS6100) manufactured by Seiko Instruments Inc. or an instrument with equivalent performance.

The specific resin composition has a low dielectric loss tangent of the cured product, and may be particularly suitably used as a resin composition for a sealing material.

### <Oxazoline Compound>

A type of oxazoline compound is not particularly limited as long as it has an oxazoline group in the molecule. The oxazoline compound preferably has two or more oxazoline groups. The specific resin composition may contain two or more types of oxazoline compounds.

From the viewpoint of reducing a dielectric loss tangent of the cured product, the oxazoline compound preferably contains an aromatic oxazoline compound.

A content of the aromatic oxazoline compound with respect to a total mass of the oxazoline compounds is preferably 50% by mass or more, more preferably 70% by mass or more, even more preferably 90% by mass or more, and may be 100% by mass.

From the viewpoint of reducing a dielectric loss tangent of the cured product, the oxazoline compound preferably contains an oxazoline compound represented by the following Formula (1) (hereinafter also referred to as a specific oxazoline compound).

A content of the specific oxazoline compound with respect to a total mass of the oxazoline compounds is preferably 50% by mass or more, more preferably 70% by mass or more, and even more preferably 90% by mass or more, and may be 100% by mass.

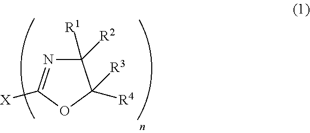

In Formula (1), each of R¹ to R⁴ independently represents a hydrogen atom or an alkyl group having 1 to 10 carbon atoms, preferably a hydrogen atom, a methyl group, or an ethyl group, and more preferably a hydrogen atom.

In Formula (1), X represents an n-valent hydrocarbon group having 1 to 10 carbon atoms, preferably an n-valent straight-chain or branched-chain hydrocarbon group having 1 to 10 carbon atoms, an n-valent alicyclic hydrocarbon group having 1 to 10 carbon atoms, or an n-valent aromatic hydrocarbon group.

In a case in which n is 2, X represents an alkylene group having 1 to 10 carbon atoms, a cycloalkylene group having 1 to 10 carbon atoms, or a phenylene group, and is preferably a phenylene group.

In Formula (1), n represents an integer from 2 to 6.

In a case in which X in Formula (1) is a phenylene group and n is 2, from the viewpoint of reducing a dielectric loss tangent of the cured product, it is preferable that the two oxazoline groups are bonded to the phenylene group in a meta or para relationship.

Specific examples of the oxazoline compound include 2,2′-(1,3-phenylene)bis-(2-oxazoline), 1,2-bis(2-oxazolinyl-2) ethane, 1,4-bis(2-oxazolinyl-2) butane, 1,8-bis(2-oxazolinyl-2) octane, and 1,4-bis(2-oxazolinyl-2)cyclohexane.

From the viewpoint of reducing a dielectric loss tangent of the cured product, a molecular weight of the oxazoline compound is preferably from 100 to 1000, more preferably from 150 to 750, and even more preferably from 180 to 500.

The oxazoline compound may be a solid or a liquid at 25° C. In a case in which the oxazoline compound is solid at 25° C., there is no particular restriction on a softening point or a melting point of the oxazoline compound.

From the viewpoint of a balance between moldability and heat resistance, the softening point or the melting point of the oxazoline compound is preferably from 40° C. to 180° C. Furthermore, from the viewpoint of handleability, the softening point or the melting point of the oxazoline compound is preferably from 50° C. to 130° C.

In the present disclosure, the softening point refers to a value measured by a ring and ball method of JIS K 7234:1986.

In the present disclosure, the melting point refers to a value measured in accordance with a visual method of JIS K 0064:1992.

A content of the oxazoline compound with respect to a total mass of the specific resin composition is preferably from 3% to 25% by mass, and more preferably from 5% to 20% by mass, from the viewpoint of a dielectric loss tangent, strength, fluidity, heat resistance, moldability or the like of the cured product.

### <Phenol Type Curing Agent>

The specific resin composition contains a phenol type curing agent. There are no particular limitations on a type of phenol type curing agent. The phenol type curing agent may be used singly or in combination of two or more types.

Examples of the phenol type curing agent include a phenolic resin and a polyhydric phenol compound, which have two or more phenolic hydroxyl groups in one molecule.

Specific examples of the phenol type curing agent is listed below, but are not limited to these.

Examples of the phenol type curing agent include a polyhydric phenol compound such as resorcin, catechol, bisphenol A, bisphenol F, and substituted or unsubstituted biphenol; a novolak type phenol resin obtained by condensing or co-condensing at least one phenolic compound selected from the group consisting of a phenolic compound such as phenol, cresol, xylenol, resorcin, catechol, bisphenol A, bisphenol F, phenylphenol and aminophenol, and a naphthol compound such as α-naphthol, β-naphthol, and dihydroxynaphthalene, with an aldehyde compound such as formaldehyde, acetaldehyde and propionaldehyde, under an acid catalyst; an aralkyl type phenolic resin such as a phenol aralkyl resin and a naphthol aralkyl resin, which are synthesized from the above-mentioned phenolic compound with dimethoxy-paraxylene, bis(methoxymethyl) biphenyl and the like; a a paraxylylene and/or metaxylylene modified phenolic resin; a melamine-modified phenolic resin; a terpene-modified phenolic resin; a dicyclopentadiene type phenolic resin and a dicyclopentadiene type naphthol resin, which are synthesized by copolymerization of the above-mentioned phenolic compound with dicyclopentadiene; a cyclopentadiene-modified phenolic resin; a polycyclic aromatic ring-modified phenolic resin; a biphenyl type phenolic resin; a triphenylmethane type phenolic resin obtained by condensing or co-condensing the above-mentioned phenolic compound with an aromatic aldehyde compound such as benzaldehyde and salicylaldehyde under an acidic catalyst; a triazine type phenolic resin such as 2-[4-[(2-hydroxy-3-(2′-ethyl) hexyl)oxy]-2-hydroxyphenyl]-4,6-bis(2,4-dimethylphenyl)-1,3,5-triazine; and a phenolic resin obtained by copolymerizing two or more of these.

From the viewpoint of reducing a dielectric loss tangent of the cured product, it is preferable that the phenol type curing agent contains one or more phenol type curing agents selected from the group consisting of an aralkyl type phenolic resin and a novolac type phenolic resin. The phenol type curing agent is described in more detail below, but are not limited to these.

The aralkyl type phenolic resin is not particularly limited, and examples thereof include a phenolic resin synthesized from at least one selected from the group consisting of a phenol compound and a naphthol compound, with dimethoxy-para-xylene, bis(methoxymethyl) biphenyl or derivatives thereof.

Specific examples of the aralkyl type phenolic resin include a phenolic resin represented by the following Formulas (XII) to (XIV).

In Formulas (XII) to (XIV), R²³ represents a hydrogen atom or a monovalent organic group having 1 to 18 carbon atoms, and may be the same or different. Each of R²², R²⁴, R²⁵ and R²⁸ represents a monovalent organic group having 1 to 18 carbon atoms, and may be the same or different. Each of R²⁶ and R²⁷ represents a hydroxyl group or a monovalent organic group having 1 to 18 carbon atoms, and may be the same or different. Each i is independently an integer from 0 to 3, each j is independently an integer from 0 to 2, each k is independently an integer from 0 to 4, and each p is independently an integer from 0 to 4. n is an average value, and each n is independently an integer from 0 to 10.

The phrase “each may be the same or different” described for R²² and the like in the above Formula means, for example, that all i's of R²² in Formula (XII) may be the same or different from each other. Furthermore, each of R²² to R³⁶ may be the same or different. For example, R²² and R²³ may all be the same or different.

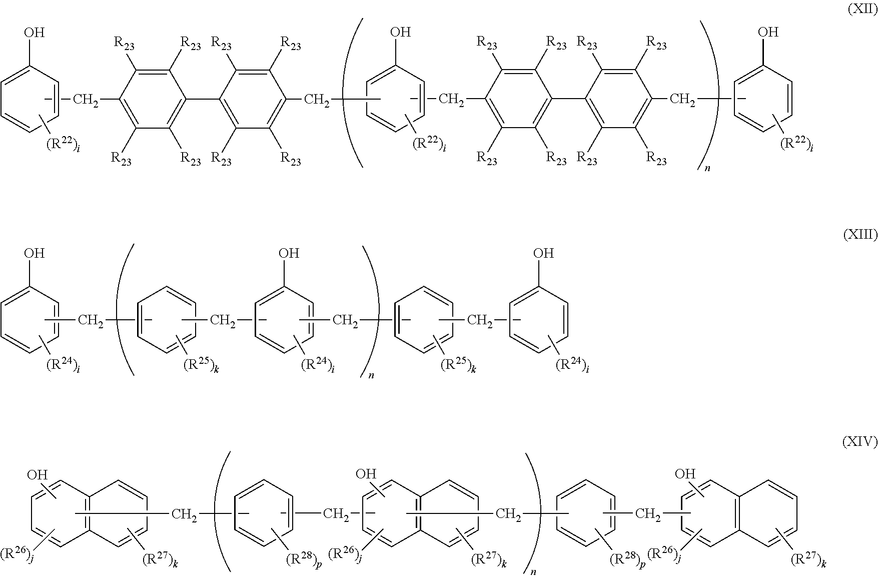

The aralkyl type phenolic resin may be a copolymer type phenolic resin with another phenolic resin. Examples of the copolymer type phenolic resin include a copolymer type phenolic resin of a triphenylmethane type phenolic resin and an aralkyl type phenolic resin, a copolymer type phenolic resin of a salicylaldehyde type phenolic resin and an aralkyl type phenolic resin, and a copolymer type phenolic resin of a novolac type phenolic resin and an aralkyl type phenolic resin.

The dicyclopentadiene type phenolic resin is not particularly limited as long as it is a phenolic resin obtained from a compound having a dicyclopentadiene structure as a raw material. For example, a phenolic resin represented by the following Formula (XV) is preferable.

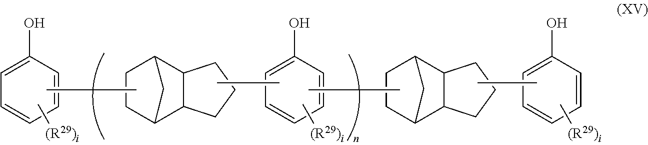

In Formula (XV), R²⁹ represents a monovalent organic group having 1 to 18 carbon atoms, and may be the same or different. Each i independently represents an integer from 0 to 3. n is an average value and represents an integer from 0 to 10.

The triphenylmethane type phenolic resin is not particularly limited as long as it is a phenolic resin obtained from an aromatic aldehyde compound as a raw material. For example, a phenolic resin represented by the following Formula (XVI) is preferred.

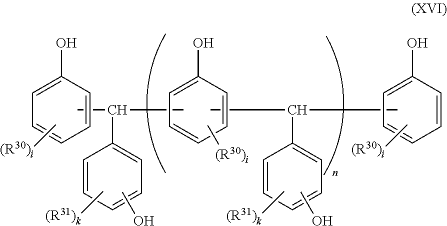

In Formula (XVI), R³⁰ and R³¹ represent monovalent organic groups having 1 to 18 carbon atoms, and may be the same or different. Each i is independently an integer from 0 to 3, and each k is independently an integer from 0 to 4. n is an average value and is an integer from 0 to 10.

The copolymer type phenolic resin of a triphenylmethane type phenolic resin and an aralkyl type phenolic resin is not particularly limited as long as it is a copolymerized phenolic resin of an aralkyl type phenolic resin and a phenolic resin obtained by using a compound having a benzaldehyde structure as a raw material. For example, a phenolic resin represented by the following Formula (XVII) is preferable.

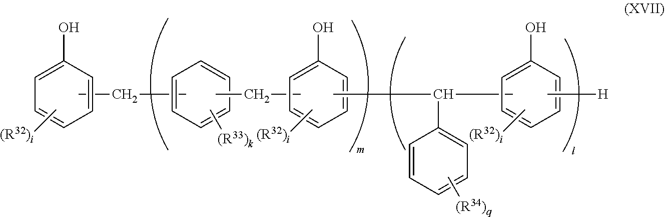

In Formula (XVII), R³² to R³⁴ represent monovalent organic groups having 1 to 18 carbon atoms, and may be the same or different. Each i is independently an integer from 0 to 3, each k is independently an integer from 0 to 4, and each q is independently an integer from 0 to 5. Each of 1 and m is an average value, and each is independently an integer from 0 to 11. However, a sum of 1 and m is an integer from 1 to 11.

The novolac type phenolic resin is not particularly limited as long as it is a phenolic resin obtained by condensing or co-condensing at least one phenolic compound selected from the group consisting of a phenolic compound and a naphthol compound with an aldehyde compound under an acid catalyst. For example, a phenolic resin represented by the following Formula (XVIII) is preferred.

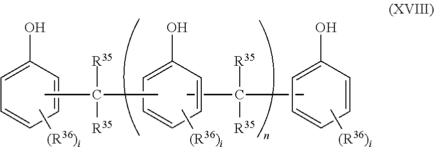

In Formula (XVIII), each R³⁵ represents a hydrogen atom or a monovalent organic group having 1 to 18 carbon atoms, and may be the same or different. Each R³⁶ represents a monovalent organic group having 1 to 18 carbon atoms, and may be the same or different. Each i independently represents an integer from 0 to 3. n is an average value and represents an integer form 0 to 10.

The phrase “each may be the same or different” described for R²² to R³⁶ in the above Formulas (XII) to (XVIII) means, for example, that all i's of R²²s in Formula (XII) may be the same or different from each other. For the other R²³ to R³⁶, the phrase also mean that each number in the formula may be the same or different from each other. Furthermore, R²² to R³⁶ may be the same or different from each other. For example, R²² and R²³ may all be the same or different, and R³⁰ and R³¹ may all be the same or different.

In the above Formulas (XII) to (XVIII), n is preferably an integer from 0 to 10. In a case in which it is 10 or less, a melt viscosity of the resin component may be not too high, and a viscosity of a resin composition during melt molding may be also low, and therefore, there may be little risk of poor filling or deformation of a bonding wire (e.g., gold wire that connect an element and a lead). The average n in one molecule is preferably set in a range from 0 to 4.

A hydroxyl group equivalent of the phenol type curing agent is not particularly limited. From the viewpoint of a balance of various properties such as the dielectric loss tangent, moldability, and electrical reliability of the cured product, it is preferably from 10 g/eq to 1000 g/eq, and more preferably from 30 g/eq to 500 g/eq.

The hydroxyl equivalent is a value calculated based on the hydroxyl value measured in accordance with JIS K 0070:1992.

From the viewpoint of reducing a dielectric loss tangent of the cured product, an equivalent ratio of a phenolic hydroxyl group of the phenol type curing agent to a oxazoline group of the oxazoline compound is preferably from 0.50 to 1.50, more preferably from 0.75 to 1.25, and even more preferably from 0.90 to 1.10.

In a case in which the phenol type curing agent is solid at 25° C., its softening point or melting point is not particularly limited. From the viewpoint of moldability and heat resistance, the softening point or melting point of the phenol type curing agent is preferably from 40° C. to 180° C. Furthermore, from the viewpoint of handleability, the softening point or melting point of the phenol type curing agent is preferably from 50° C. to 130° C.

From the viewpoint of reducing a dielectric loss tangent of the cured product, a content of the phenol type curing agent with respect to a total mass of the specific resin composition is preferably from 0.5% by mass to 40% by mass, more preferably from 1% by mass to 30% by mass, and even more preferably from 2% by mass to 20% by mass.

### <Inorganic Filler>

The specific resin composition contains an inorganic filler.

Examples of the inorganic filler include inorganic materials such as silica filler (e.g., fused silica, and crystalline silica), glass, alumina, calcium carbonate, zirconium silicate, calcium silicate, silicon nitride, aluminum nitride, boron nitride, beryllia, zirconia, zircon, fosterite, steatite, spinel, mullite, titania, talc, clay, and mica. The inorganic filler having a flame retardant effect may be also used. Examples of the inorganic filler having a flame retardant effect include aluminum hydroxide, magnesium hydroxide, a composite metal hydroxide such as a composite hydroxide of magnesium and zinc, and zinc borate.

Among the above, from the viewpoint of reducing a dielectric loss tangent of the cured product, the inorganic filler is preferably a silica filler.

A shape of the inorganic filler is not particularly limited, and it may be particulate or non-particulate such as fibrous.

The specific resin composition may contain two or more types of inorganic fillers.

In a case in which the inorganic filler is in particulate form, an average particle size is preferably from 0.1 μm to 100 μm, more preferably from 0.3 μm to 50 μm, and even more preferably from 0.5 μm to 10 μm. In a case in which the average particle size is 0.1 μm or more, an increase in viscosity of the specific resin composition tends to be suppressed. In a case in which the average particle size is 100 μm or less, a filling property tends to be improved.

The average particle size of the inorganic filler is determined as a volume average particle size (D50) using a particle size distribution measuring device of a laser scattering diffraction method.

From the viewpoint of fluidity, a specific surface area of the inorganic filler is preferably from 1.3 m²/g to 10.0 m²/g, more preferably from 2.0 m²/g to 8.0 m²/g, and even more preferably from 2.5 m²/g to 7.5 m²/g.

From the viewpoint of both improving a moldability of the specific resin composition and reducing a dielectric loss tangent of the cured product, a content of the inorganic filler with respect to a total mass of the specific resin composition is preferably from 60% by mass to 80% by mass, and more preferably from 60% by mass to 75% by mass.

From the viewpoint of a fluidity of the specific resin composition and a relative dielectric constant and dielectric loss tangent of the cured product, a volume ratio of the inorganic filler with respect to an entire specific resin composition is preferably 60% by volume to 80% by volume, more preferably 63% by volume to 78% by volume, and even more preferably 65% by volume to 75% by volume.

### <Curing Accelerator>

The specific resin composition in the present disclosure may contain a curing accelerator. A type of the curing accelerator is not particularly limited, and may be selected depending on a type of the oxazoline compound or the phenol type curing agent, a desired property of the specific resin composition or the like.

From the viewpoint of reducing a dielectric loss tangent of the cured product, the curing accelerator is preferably an acid catalyst, more preferably at least one of a sulfonic acid type curing accelerator and a phosphoric acid type curing accelerator, and even more preferably a sulfonic acid type curing accelerator.

Examples of the sulfonic acid type curing accelerator include methyl p-toluenesulfonate, ethyl p-toluenesulfonate, propyl p-toluenesulfonate, and methoxyethyl p-toluenesulfonate.

Examples of the phosphoric acid type curing accelerator include phosphorous acid.

Among the above, from the viewpoint of reducing a dielectric loss tangent of the cured product, it is preferable that the curing accelerator is one or more selected from the group consisting of methyl p-toluenesulfonate, ethyl p-toluenesulfonate, and propyl p-toluenesulfonate.

In a case in which the specific resin composition contains a curing accelerator, an amount is preferably from 0.1 parts by mass to 30 parts by mass, and more preferably from 1 part by mass to 15 parts by mass, with respect to 100 parts by mass of the resin component (i.e., a total amount of the oxazoline compound and the phenol type curing agent). In a case in which the amount of the curing accelerator is 0.1 parts by mass or more with respect to 100 parts by mass of the resin component, the resin tends to cure well in a short time. In a case in which the amount of the curing accelerator is 30 parts by mass or less with respect to 100 parts by mass of the resin component, a curing speed may be not too fast, and an excellent molded product tends to be obtained.

<Curable Compound Other than Oxazoline Compound>

The specific resin composition may contain a curable compound other than the oxazoline compound. Specific examples thereof include a fluororesin and an epoxy resin.

From the viewpoint of reducing a dielectric loss tangent of the cured product, a content of the curable compound other than the oxazoline compound with respect to a total mass of the specific resin composition is preferably 5% by mass or less, more preferably 3% by mass or less, even more preferably 1% by mass or less, and it is particularly preferable that the specific resin composition does not contain any curable compound other than the oxazoline compound.

<Curing Agent Other than Phenol Type Curing Agent>

The specific resin composition may contain a curing agent other than a phenol type curing agent. Specific examples thereof include an amine type curing agent, a polymercaptan type curing agent, a polyaminoamide type curing agent, an isocyanate type curing agent, and a blocked isocyanate type curing agent.

From the viewpoint of reducing a dielectric loss tangent of the cured product, a content of a curing agent other than the phenol type curing agent with respect to a total mass of the specific resin composition is preferably 5% by mass or less, more preferably 3% by mass or less, even more preferably 1% by mass or less, and it is particularly preferable that the specific resin composition does not contain any curing agent other than the phenol type curing agent.

### <Various Additives>

In addition to the above-mentioned components, the specific resin composition may contain various additives such as a coupling agent, an ion exchanger, a release agent, a flame retardant, a colorant and a plasticizer, as exemplified below. In addition to the additives exemplified below, the specific resin composition may contain various additives well known in the art, as necessary.

### <Coupling Agent>

The specific resin composition may contain a coupling agent. From the viewpoint of increasing an adhesion between the resin component and the inorganic filler, it is preferable that the specific resin composition contains a coupling agent. Examples of the coupling agent include known coupling agents, for example, a silane type compound such as an epoxysilane, a mercaptosilane, an aminosilane, an alkylsilane, an ureidosilane, a vinylsilane, and a disilazane, a titanium type compound, an aluminum chelate compound, and an aluminum/zirconium type compound.

In a case in which the specific resin composition contains the coupling agent, an amount of the coupling agent is preferably from 0.05 parts by mass to 5 parts by mass, and more preferably from 0.1 parts by mass to 2.5 parts by mass, with respect to 100 parts by mass of the inorganic filler. In a case in which the amount of the coupling agent is 0.05 parts by mass or more with respect to 100 parts by mass of the inorganic filler, an adhesiveness to an electronic component device such as a lead frame tends to be improved. In a case in which the amount of the coupling agent is 5 parts by mass or less with respect to 100 parts by mass of the inorganic filler, a moldability of a package tends to be improved.

### <Ion Exchanger>

The specific resin composition may contain an ion exchanger. In a case in which the specific resin composition is used as a sealing material, it is preferable that the specific resin composition contains an ion exchanger, from the viewpoint of improving a moisture resistance and high-temperature storage characteristics of an electronic component device including a sealed element. The ion exchanger is not particularly limited, and a conventionally known one may be used. Specific examples thereof include a hydrotalcite compound and a hydrated oxide of at least one element selected from the group consisting of magnesium, aluminum, titanium, zirconium, and bismuth. The ion exchanger may be used singly or in combination of two or more types. Among them, a hydrotalcite represented by the following Formula (A) is preferable.

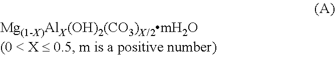

In a case in which the specific resin composition contains the ion exchanger, a content thereof is not particularly limited as long as it is sufficient to capture ions such as halogen ions. For example, the content is preferably from 0.1 parts by mass to 30 parts by mass, and more preferably from 1 part by mass to 10 parts by mass, with respect to 100 parts by mass of the resin component (i.e., a total amount of the oxazoline compound and the phenol type curing agent).

### <Mold Release Agent>

The specific resin composition may contain a mold release agent from the viewpoint of excellent releasability from the mold during molding. The mold release agent is not particularly limited, and conventionally known mold release agents may be used. Specific examples thereof include a carnauba wax, a higher fatty acid such as montanic acid and stearic acid, a higher fatty acid metal salt, an ester wax such as a montanic acid ester, a polyolefin wax such as an oxidized polyethylene and non-oxidized polyethylene, and the like. The mold release agent may be used singly or in combination of two or more types.

In a case in which the specific resin composition contains the release agent, an amount is preferably from 0.01 parts by mass to 10 parts by mass, more preferably from 0.1 parts by mass to 5 parts by mass, with respect to 100 parts by mass of a resin component (i.e., a total amount of the oxazoline compound and the phenol type curing agent). In a case in which the amount of the release agent is 0.01 parts by mass or more with respect to 100 parts by mass of the resin component, sufficient release properties tend to be obtained. In a case in which the amount is 10 parts by mass or less, better adhesion tends to be obtained.

### <Flame Retardant>

The specific resin composition may contain a flame retardant. The flame retardant is not particularly limited, and conventionally known ones may be used. Specific examples thereof include an organic or inorganic compound containing a halogen atom, an antimony atom, a nitrogen atom or a phosphorus atom, metal hydroxides, and the like. The flame retardants may be used singly or in combination of two or more types.

In a case in which the specific resin composition contains the flame retardant, there are no particular restrictions on an amount thereof, as long as it is sufficient to obtain the desired flame retardant effect. For example, the amount is preferably from 1 part by mass to 30 parts by mass, and more preferably from 2 parts by mass to 20 parts by mass, with respect to 100 parts by mass of the resin component (i.e., a total amount of the oxazoline compound and the phenol type curing agent).

### <Colorant>

The specific resin composition may contain a colorant. Examples of the colorant include known colorants such as a carbon black, an organic dye, an organic pigment, a titanium oxide, a red lead, and a red iron oxide. A content of the colorant may be appropriately selected depending on the purpose. The colorant may be used singly or in combination of two or more.

### [Method of Preparing Specific Resin Composition]

A method of preparing the specific resin composition is not particularly limited. Examples of a general method include: thoroughly mixing a predetermined amount of components using a mixer or the like; melt-kneading the components using a mixing roll, extruder or the like; cooling; and pulverizing the components. More specifically, for example, a method includes: uniformly stirring and mixing a predetermined amount of components described above; kneading the components using a kneader, roll, extruder or the like that have been heated to from 70° C. to 140° C.; cooling, and pulverizing the components.

### [Electronic Component Device]

The electronic component device in the present disclosure includes: a support member, an element disposed on the support member, and a cured product of the specific resin composition that seals the element.

Examples of the electronic component device include devices in which elements (active elements such as semiconductor chips, transistors, diodes and thyristors, and passive elements such as capacitors, resistors and coils) are mounted on a support member such as a lead frame, a pre-wired tape carrier, a wiring board, a glass, a silicon wafer, or an organic substrate to form an element portion, and the element portion is sealed with a specific resin composition, which is for example, a high-frequency device.

More specific examples of the devices include typical resin-sealed ICs such as DIP (Dual Inline Package), PLCC (Plastic Leaded Chip Carrier), QFP (Quad Flat Package), SOP (Small Outline Package), SOJ (Small Outline J-lead package), TSOP (Thin Small Outline Package), and TQFP (Thin Quad Flat Package), which have a structure in which an element is fixed on a lead frame, and a terminal portion of the element such as a bonding pad and a lead portion are connected by wire bonding, bumps or the like, and then sealed by transfer molding using a specific resin composition; a TCP (Tape Carrier Package) having a structure in which elements connected to a tape carrier via bumps are sealed with the specific resin composition; a COB (Chip On Board) module, a hybrid IC, a multi-chip module or the like, which have a structure in which elements connected to wiring formed on a support member by wire bonding, flip chip bonding, solder or the like are sealed with the specific resin composition; and a BGA (Ball Grid Array), a CSP (Chip Size Package), a MCP (Multi Chip Package) or the like, which have a structure in which elements are mounted on a surface of a support member having a terminal for wiring board connection formed on aback side, the elements are connected to the wiring formed on the support member by bumps or wire bonding, and then the elements are sealed with the specific resin composition. The specific resin composition may also be suitably used in printed wiring boards.

A type of the support member is not particularly limited, and a support member generally used in the manufacture of electronic component devices may be used.

The electronic component may include an antenna, or may include an antenna and an element other than an antenna. The antenna is not limited as long as it functions as an antenna, and may be an antenna element or wiring.

In addition, in the electronic component device in the present disclosure, if necessary, other electronic components may be placed on a surface of the support member opposite to the surface on which the electronic component is placed. The other electronic components may be sealed with the resin composition described above, may be sealed with another resin composition, or may not be sealed.

### [Method of Producing Electronic Component Device]

A method of producing an electronic component device in the present disclosure includes: disposing an element on or above a support member; and sealing the element with the specific resin composition.

A method of carrying out each of the above processes is not particularly limited, and each process may be carried out by a general method. In addition, a type of the support member and the element used in a production of the electronic component device are not particularly limited, and the support member and the element generally used in a production of an electronic component device may be used.

Examples of a method of sealing elements using the specific resin composition include a low-pressure transfer molding, an injection molding, and a compression molding. Among them, a low-pressure transfer molding is the most common.

### EXAMPLES

The present disclosure will be specifically described below with reference to examples. However, the present disclosure is not limited to these examples. It is to be noted that numerical values in a table mean “parts by mass” unless otherwise specified.

### Examples 1 to 2 and Comparative Examples 1 to 2

Components shown below were mixed in the mixing ratios (parts by mass) shown in Table 1 to prepare resin compositions of examples and comparative examples. The specific resin compositions were solid at room temperature and normal pressure.

A volume ratio of an inorganic filler with respect to an entire resin composition in Example 1 and Comparative Example 1 was 65% by volume, and a volume ratio of an inorganic filler with respect to an entire resin composition in Example 2 and Comparative Example 2 was 72% by volume.

Table 1 also summarizes an equivalent ratio of a phenolic hydroxyl group of a phenol type curing agent to an oxazoline group of an oxazoline compound.
Oxazoline compound: 2,2′-(1,3-phenylene)bis-(2-oxazoline), molecular weight 216
Epoxy resin A: biphenyl aralkyl type epoxy resin
Epoxy resin B: biphenyl type epoxy resin
Phenol type curing agent: biphenyl aralkyl type phenol type curing agent
Cure accelerator A: methyl p-toluenesulfonate
Cure accelerator B: adduct of tributylphosphine and 1,4-benzoquinone
Coupling agent: N-phenyl-3-aminopropyltrimethoxysilane
Inorganic filler A: silica filler, average particle size 6.0 μm, specific surface area 2.8 m²/g
Inorganic filler B: silica filler, average particle size 0.5 μm, specific surface area 6.6 m²/g
Colorant: carbon black

### <<Measurement of Curing Start Temperature>>

A curing start temperature of the resin compositions obtained in the examples and comparative examples was measured by differential scanning calorimetry using a Discovery DSC 250 manufactured by TA instruments. The curing start temperature was measured in a range from 40° C. to 300° C. at a heating rate of 10° C./min, and a peak onset temperature (peak rise temperature) was taken as the curing start temperature. The results are summarized in Table 1.

<<Measurement of relative dielectric constant Dk and dielectric loss tangent Df>>

The resin compositions obtained in the examples and comparative examples were loaded into a vacuum hand press and molded under conditions of a mold temperature of 175° C., a molding pressure of 6.9 MPa, and a curing time of 600 seconds. Post-curing was performed at 180° C. for 6 hours to obtain a plate-shaped cured product (length 12.5 mm, width 25 mm, and thickness 0.2 mm).

Using the plate-shaped cured product as a test specimen, a dielectric constant measuring device (product name “Network Analyzer N5227A” manufactured by Agilent Technologies) was used to measure the relative dielectric constant Dk and dielectric loss tangent Df at a temperature of 25±3° C. and approximately 5 GHZ, and each was evaluated based on the following evaluation criteria. The results are summarized in Table 1. The measured values are also summarized in Table 1.

### (Evaluation Criteria)

A: The relative dielectric constant Dk was less than 3.60.
B: The relative dielectric constant Dk was 3.60 or greater.

### (Evaluation Criteria)

A: The dielectric loss tangent Df was less than 0.0075.
B: The dielectric loss tangent Dk was 0.0075 or greater.

### <Measurement of Glass Transition Temperature (Tg) of Resin Composition>

A glass transition temperature of the specific resin compositions was measured according to “extrapolated glass transition onset temperature” described in a method for determining the glass transition temperature in “Testing methods for transition temperatures of plastics” in JIS K 7121 (1987). The results are summarized in Table 1.

### <Measurement of Linear Expansion Coefficient>

The resin compositions obtained in the examples and comparative examples were molded using a transfer molding machine under conditions of a molding temperature of 175° C., a molding pressure of 6.9 MPa, and a curing time of 120 seconds to obtain plate-shaped molded products (length 127 mm, width 12.7 mm, and thickness 6.4 mm).

Then, a distortion of the molded products ware plotted against temperature using thermomechanical analysis based on JIS K 7197:2012, and a slope of a tangent line was determined in a range from 80° C. to 120° C. and a range from 200° C. to 240° C. The slope of the tangent line in the range from 80° C. to 120° C. is shown as CTE1 (ppm/° C.), and the slope of the tangent line in the range from 200° C. to 240° C. is shown as CTE2 (ppm/° C.) in Table 1.

A test load during measurement is 5 g and a heating rate is 5° C./min.

The linear expansion coefficient was measured using a TMA high-precision two-sample thermal analyzer (instrument name SS6100) manufactured by Seiko Instruments Inc.

### <<Measurement of Mold Shrinkage Rate>>

The resin compositions were molded using a transfer molding machine at a molding temperature of 175° C., a molding pressure of 6.9 MPa, and a curing time of 120 seconds to obtain plate-shaped molded products (length 127 mm, width 12.7 mm, and thickness 6.4 mm).

A mold shrinkage rate A (%) was calculated using the following Formula from a previously measured length D of a mold cavity at 25° C. and a length d of a molded product at room temperature (25° C.). The results are summarized in Table 1.

$$Mold shrinkage rate A ( \% ) = ( ( D - d ) / D ) \times 100$$

The resin compositions were molded using a transfer molding machine at a molding temperature of 175° C., molding pressure of 6.9 MPa, and a curing time of 120 seconds to obtain plate-shaped molded products (length 127 mm, width 12.7 mm, and thickness 6.4 mm). The molded products were post-cured at 175° C. for 5 hours to obtain plate-shaped cured products.

A mold shrinkage rate B (%) was calculated using the following Formula from a previously measured length D of a mold cavity at 25° C. and a length d of a cured product at room temperature (25° C.). The results are summarized in Table 1.

$$Mold shrinkage rate B ( \% ) = ( ( D - d ) / D ) \times 100$$

TABLE 1

| | | | | Comparative | Comparative |
|---|---|---|---|---|---|
| | | Example 1 | Example 2 | Example 1 | Example 2 |
| Oxazoline compound | | 100 | 100 | — | — |
| Epoxy resin A | | — | — | 80 | 80 |
| Epoxy resin B | | — | — | 20 | 20 |
| Phenol type | | 184 | 184 | 78.8 | 78.8 |
| curing agent | | | | | |
| Curing accelerator A | | 10 | 12 | — | — |
| Curing accelerator B | | — | — | 2 | 2 |
| Coupling agent | | 5 | 5 | 5 | 5 |
| Inorganic filler A | | 857 | 1198 | 549 | 758 |
| Inorganic filler B | | 214 | 299 | 137 | 190 |
| Colorant | | 2.75 | 3.61 | 1.76 | 2.28 |
| Equivalent ratio of a phenolic | | 1.00 | 1.00 | — | — |
| hydroxyl group of a phenol | | | | | |
| type curing agent to an | | | | | |
| oxazoline group of an | | | | | |
| oxazoline compound | | | | | |
| Curing start temperature (° C.) | | 150 | 150 | 130 | 130 |
| Relative | Evaluation | A | A | A | A |
| dielectric | Measured | 3.58 | 3.53 | 3.49 | 3.49 |
| constant | value | | | | |
| Dielectric | Evaluation | A | A | B | A |
| loss | Measured | 0.0066 | 0.0056 | 0.0080 | 0.0066 |
| tangent | value | | | | |

| | | | | |
|---|---|---|---|---|
| Tg(° C.) | 106.7 | 121 | 118.2 | 126 |
| CTE1 (ppm/° C.) | 1.41 | 1.00 | 1.92 | 1.40 |
| CTE2 (ppm/° C.) | 5.33 | 5.40 | 6.73 | 5.40 |
| Molding shrinkage | 0.30 | 0.33 | 0.41 | 0.34 |
| rate A (%) | | | | |
| Molding shrinkage | 0.45 | 0.35 | 0.60 | 0.39 |
| rate B (%) | | | | |

As shown in Table 1, when comparing the resin composition of Example 1 with the resin composition of Comparative Example 1, both of which have volume percentage of inorganic filler of 65% by volume, the dielectric loss tangent of the cured product obtained from the resin composition of Example 1 is lower.

As shown in Table 1, when comparing the resin composition of Example 1 with the resin composition of Comparative Example 1, both of which have volume percentage of inorganic filler of 72% by volume, the dielectric loss tangent of the cured product obtained from the resin composition of Example 2 is lower.

It can also be seen that the resin compositions of the Examples have similar linear expansion coefficients and mold shrinkage rates to the resin compositions of the Comparative Examples.

1. A resin composition comprising a compound having an oxazoline group, a phenol type curing agent, and an inorganic filler.

2. The resin composition according to claim 1, wherein the compound having an oxazoline group comprises an aromatic oxazoline compound.

3. The resin composition according to claim 1, wherein a molecular weight of the compound having an oxazoline group is from 100 to 1000.

4. The resin composition according to claim 1, wherein an equivalent ratio of a phenolic hydroxyl group of the phenol type curing agent to the oxazoline group of the compound having an oxazoline group is from 0.75 to 1.25.

5. The resin composition according to claim 1, further comprising at least one of a sulfonic acid type curing accelerator or a phosphoric acid type curing accelerator.

6. The resin composition according to claim 1, the resin composition being solid at 25° C.

7. The resin composition according to claim 1, the resin composition having a curing initiation temperature of 175° C. or less.

8. A sealing material comprising the resin composition according to claim 1.

9. An electronic component device comprising:
a support member,
an element disposed on the support member, and
a cured product of the resin composition according to claim 1 that seals the element.

10. A method of producing an electronic component device, the method comprising:
disposing an element on or above a support member; and
sealing the element with the resin composition according to claim 1.
